(19) United States
(12) Patent Application Publication
(10) Pub. No.: US 2025/0024644 A1
(43) Pub. Date: Jan. 16, 2025

(54) HEAT SINK WITH HEAT PIPE FOR AN ELECTRONIC COMPONENT AND A CORRESPONDING ASSEMBLY

(71) Applicant: RITTAL GMBH & CO. KG, Herborn (DE)

(72) Inventor: Juan Carlos CACHO ALONSO, Braunschweig (DE)

(21) Appl. No.: 18/712,896

(22) PCT Filed: Dec. 15, 2022
(86) PCT No.: PCT/DE2022/100955

§ 371 Date: May 23, 2024

(30) Foreign Application Priority Data
Jan. 13, 2022 (DE) 10 2022 100 756.1

(51) Int. Cl. H05K 7/20

(52) U.S. Cl. CPC H05K 7/20336; H05K 7/2039

(57) ABSTRACT

A heat sink for an electronic component, the heat sink] having an air heat exchanger with a plurality of fins which delimit air ducts through the air heat exchanger, wherein the fins are at least partially in the form of heat pipes. Furthermore, a corresponding assembly is described.

### CROSS-REFERENCE TO RELATED APPLICATIONS

This application is a U.S. National Phase Application under 35 U.S.C. 371 of International Application No. PCT/DE2022/100955, filed on Dec. 15, 2022, which claims the benefit of German Patent Application No. 10 2022 100 756.1, filed on Jan. 13, 2022. The entire disclosures of the above applications are incorporated herein by reference.

### BACKGROUND

This section provides background information related to the present disclosure which is not necessarily prior art.

### TECHNICAL FIELD

The invention is based on a heat sink for an electronic component, the heat sink having an air heat exchanger with a plurality of fins which delimit air ducts through the air heat exchanger. Such a heat sink is described in DE 10 2004 023 037 B4.

### DISCUSSION

With increasing power density of electronic components, for instance IT components or inverters, and with increasing computing power of microchips (CPUs, GPUs), their heat development also increases. The air heat exchangers used hitherto are frequently in the form of aluminum blocks and therefore have a limited dissipation capacity. Further developments, for instance in the field of microchip technology, enable chip powers of up to 400 watts per chip. Owing to the increased power density, the known air heat exchangers are no longer suitable for dissipating the resulting power loss to a sufficient extent. Although new cooling technologies such as “direct chip cooling” enable the component to be cooled effectively, however, these technologies are significantly more complex and comparatively less robust to failures than, for example, the air heat exchangers integrated into the CPU or GPU. The heat pipes known from the prior art on the basis of copper tubes and aluminum fins also have only a limited cooling capacity.

### SUMMARY

This section provides a general summary of the disclosure and is not a comprehensive disclosure of its full scope or all of its features.

It is therefore one aspect of the invention to further develop a heat sink with an air heat exchanger in such a way that it has the highest possible cooling power density.

Accordingly, provision is made in a heat sink for the fins of the air heat exchanger to be at least partially in the form of a heat pipe. As a result of the use of the heat pipes, the power loss is distributed efficiently over the volume of the air heat exchanger, as a result of which the heat exchange to the air flowing through the air heat exchanger is improved and therefore the efficiency of the heat sink is increased.

The fins in the form of heat pipes can each have at least one vertical hollow conductor or microchannel in which a working medium of the heat pipe is guided. Accordingly, the fins can be in the form of medium-guiding hollow fins. The hollow fins can be formed between an evaporation zone in a lower region of the air heat exchanger and a cavity in the upper region of the air heat exchanger and open into the latter. Preferably, the heat pipes or the fins can extend parallel to one another. Accordingly, the fins in the form of hollow fins can fluidically connect the medium volume of the evaporation zone to the cavity, such that all the heat pipes can be fluidically connected to one another via the evaporation zone and the cavity.

The air heat exchanger can be a microchannel heat exchanger which is preferably free of forward flow and return flow and has a hermetically encapsulated volume of a working medium. The air heat exchanger can be provided, for example, by virtue of the fact that, in the case of a commercially available microchannel heat exchanger, possibly present forward flows and return flows are closed after the microchannel heat exchanger has been filled with a working medium, for example with a 2-phase refrigerant, such that the working medium is hermetically encapsulated in the closed microchannel heat exchanger.

The microchannel heat exchanger can have a plurality of microchannels which each form one of the heat pipes. The microchannels can be connected to one another by the evaporation zone and possibly an upper cavity. This results in an improved distribution of the power loss over all the microchannels, as a result of which the heat dissipation capacity is increased. This likewise contributes to avoiding hotspots in the electronic component. Furthermore, the loss area can be increased significantly beyond the contact area of the electronic component with the heat sink.

Preferably, each microchannel of the plurality of microchannels of the microchannel heat exchanger forms in each case one of the heat pipes.

The microchannel heat exchanger can have an evaporation zone into which the microchannels open with a first end and via which the microchannels are fluidically connected to one another. The evaporation zone can be a reservoir for a working medium of the heat pipes which are formed by the microchannels.

The evaporation zone can be in direct or indirect thermal contact with a mounting side of the heat sink for mounting the heat sink on an electronic component to be cooled. Preferably, the mounting side of the heat sink and other constituents of the heat sink, in particular the heat pipes of the heat sink, for example the microchannel heat exchanger providing the heat pipes, are formed in one piece, preferably from the same material. Such a heat sink can be produced, for example, with the aid of an additive manufacturing method, for instance by means of build-up welding. The one-piece nature ensures optimum heat transfer between the mounting side and the heat pipes or between the mounting side and the evaporation zone of the heat pipes. Suitable materials comprise aluminum or an aluminum-containing alloy.

The microchannel heat exchanger can have a cavity into which the microchannels open with their second ends arranged opposite the first. The cavity can be a constituent of a condensation zone of the heat pipes. However, since, according to function, the condensation takes place along the fins in the form of heat pipes owing to the air passing through the air heat exchanger, the heat sink does not necessarily require a separate condensation zone, as is known in heat pipe arrangements known from the prior art. Therefore, the cavity can have, in particular, the function of connecting the second ends of the plurality of heat pipes to one another in order to achieve fluidic exchange between the heat pipes and therefore optimization of the efficiency of the heat sink by better distribution of the cooling load over its heat sink volume.

In a preferred embodiment, the microchannel heat exchanger has, in addition to the fins in the form of heat pipes, further fins which extend substantially parallel to one another and spaced apart from one another and substantially perpendicular to the fins in the form of heat pipes. In the installation situation, the fins in the form of heat pipes are oriented vertically, or substantially vertically, or at least in sections vertically, in order to ensure optimum function of the heat pipes. Consequently, the further fins additionally present in the preferred embodiment can be oriented substantially horizontally in the installation situation. The further fins can have substantially two functions. Firstly, the fins serve for heat transfer between the heat pipes and therefore for increasing the efficiency of the heat sink by virtue of a required cooling load being distributed better over the heat sink volume or a power loss resulting locally in the electronic component to be cooled being dissipated in an optimum manner. Secondly, the further fins form an additional surface for the heat transfer between the heat sink and the air flowing through the heat sink, in particular between the heat pipes and the air flowing through the heat sink.

The further fins can therefore be in the form of solid fins made of a thermally conductive material, adjacent fins in the form of heat pipes being thermally coupled to one another via a plurality of the further fins.

The fins in the form of heat pipes can extend parallel to one another and are at a distance from one another which is less than 10 mm, preferably less than 8 mm and particularly preferably less than 6 mm.

The fins in the form of heat pipes can each have a plurality of vertical and parallel microchannels which are arranged one behind the other in a longitudinal direction of the fins in the form of heat pipes. Where reference is made here to vertically oriented fins for forming the heat pipes, the installation situation of the heat sink on an electronic component is described here, in which the heat sink is preferably oriented in such a way that the heat pipes are oriented vertically in order to provide the highest possible efficiency of the heat pipes. For this purpose, it may be necessary, for example, for the heat pipes to extend perpendicularly to a mounting side with which the heat sink is mounted on an electronic component to be cooled. For this purpose, as is entirely customary in the case of CPUs, for example, it can have a substantially horizontal fastening side via which the heat sink can be mounted and the electronic component dissipates its power loss to the surroundings.

The fins in the form of heat pipes can each have a plurality of vertical and parallel microchannels which are arranged one behind the other in a longitudinal direction of the fins in the form of heat pipes.

According to another aspect, an assembly comprising at least one heat sink of the type described above and an electronic component is described, wherein the heat sink is arranged in thermal contact on the electronic component. In this case, the heat pipes are in the form of vertical hollow conductors or microchannels or have such vertical hollow conductors or microchannels. The vertical hollow conductors or microchannels can extend vertically at least in sections in order to ensure optimum functioning of the heat pipes. The heat pipes can also be arranged at an angle to the vertical, wherein the functioning of the heat pipe decreases with decreasing height difference between an evaporation zone and an upper end, for example a condensation zone. Analogously, the heat pipes should extend substantially perpendicularly to the electronic component to be cooled in order to optimize the dissipation of heat from the electronic component.

The heat sink can be in thermal contact with the electronic component by way of a mounting side of the heat sink which can be a heat coupling-in side of an evaporation zone of the heat pipes.

The heat sink can have, on an outer side opposite the evaporation zone, a cavity into which the vertical hollow conductors or microchannels of the heat pipes open, such that a fluidic transition between the heat pipes is provided via the cavity.

Furthermore, the assembly can have an air flow generator, for example a fan, by means of which air is transported through the air-conducting channels, such that the air flows around the fins in the form of heat pipes. The fan can be, for example, a radial fan.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations and are not intended to limit the scope of the present disclosure.

Further details of the invention will be explained with reference to the following figures. In the figures:

FIG. 1 shows an exemplary embodiment of a heat sink in the partially sectioned perspective illustration;

FIG. 2 shows a horizontal cross section through the embodiment according to FIG. 1; and

FIG. 3 shows an embodiment of an assembly according to the invention comprising a heat sink and an IT component.

### DETAILED DESCRIPTION

Example embodiments will now be described more fully with reference to the accompanying drawings.

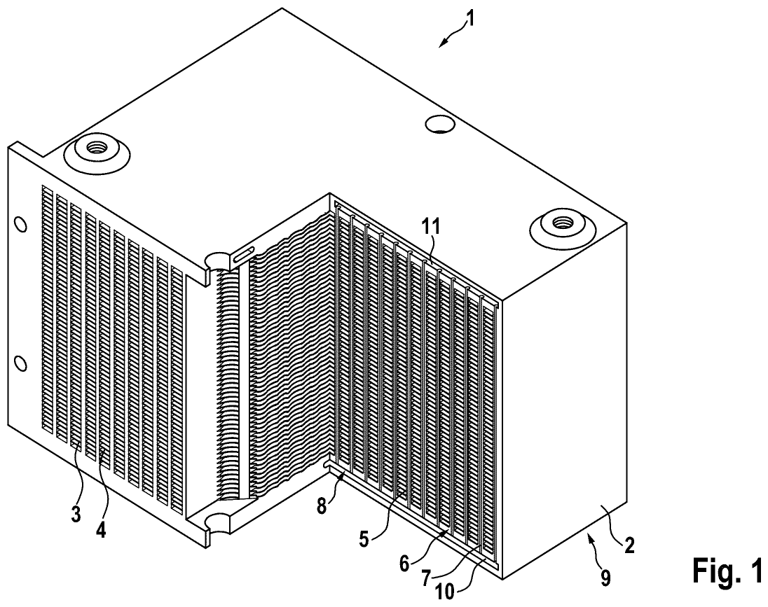

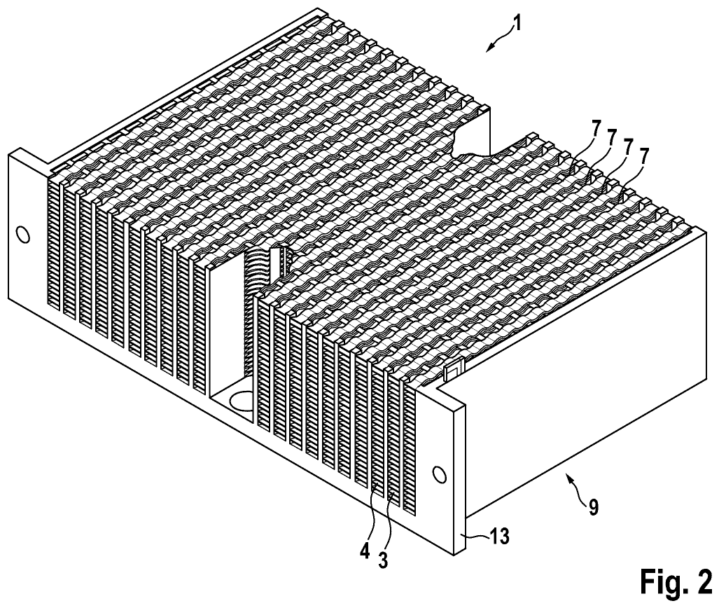

FIGS. 1 and 2 show a first embodiment of a heat sink 1 according to the invention. The heat sink 1 can be provided in one piece, for example be constructed in an additive manufacturing method, for instance by means of build-up welding, from a thermally conductive material, preferably from aluminum or aluminum alloy. The additive methods known from the prior art are in particular suitable for forming the fine structures in the manner of a microchannel heat exchanger which is a substantial constituent of the embodiment of the heat sink 1 according to FIG. 1.

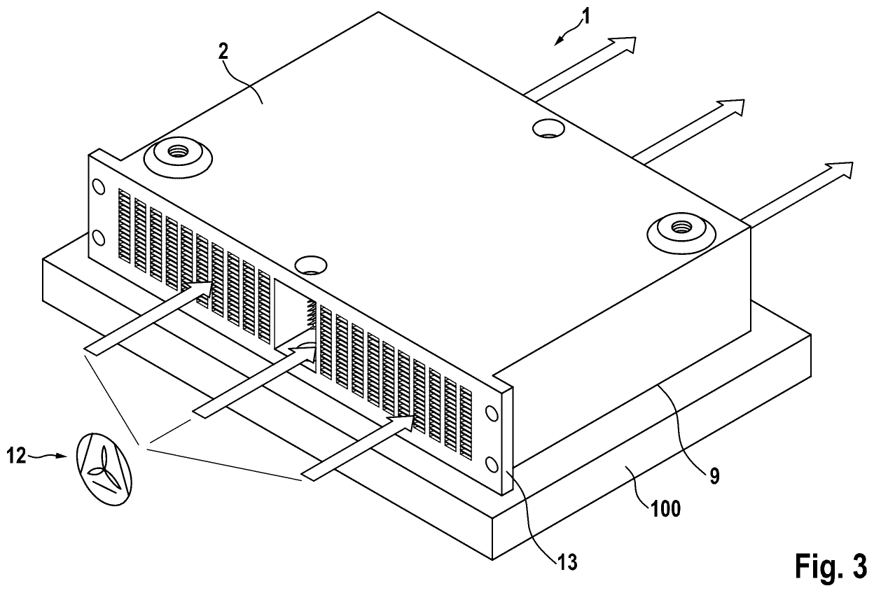

Accordingly, the heat sink 1 has an air heat exchanger 2 with a plurality of fins 3, 4 which delimit air ducts 5 through the air heat exchanger 2, as is known in principle in the case of heat sinks for IT components known from the prior art. The heat sink according to the invention is characterized in that the fins 3, 4 are at least partially in the form of heat pipes 6. In the present case, the fins 3 which are vertical in the illustration are in the form of hollow conductors or microchannels 7 in which a working medium 8 of the heat pipe 6 is guided. In the base region, the heat sink 1 has a mounting side 9 via which the heat sink 1 can be mounted on an IT component (not illustrated, cf. FIG. 3, there IT component 100) to be cooled. The power loss dissipated by the IT component to be cooled can be coupled directly into the evaporation zone 10 of the heat pipes 6 via the mounting side 9. All the heat pipes 6 are fluidically connected to one another via the evaporation zone, such that even in the case of locally occurring heat coupling into the mounting side, which can depend on the geometry and design of the IT component to be cooled, optimum distribution of the power loss over the mounting side 9 or the evaporation zone 10 takes place and therefore the heat pipes 6 can be acted on equally or approximately in the same way and consequently contribute to dissipating the power loss.

The fins 3 in the form of hollow conductors or microchannels 7 are oriented substantially vertically and spaced apart from one another in parallel, it being possible for the vertical fins 3 to be at a distance of less than 10 mm. Owing to the high packing density of the vertical fins 3 and therefore of the heat pipes, high cooling power can be provided with a comparatively small structural volume of the heat sink 1. Adjacent vertical fins 3 are connected to one another via further horizontally oriented solid fins 4 and, owing to the good thermal conductivity both of the vertical fins 3 and of the further horizontal fins 4, optimum heat exchange between the heat pipes and the air stream can take place in the case of an air stream passing through the heat sink 1. The horizontal fins 4 therefore not only increase the effective surface area between air and heat sink 1 which is effective for the heat transfer, but they also serve for heat transfer and therefore for load equalization between the heat pipes.

Formed on an upper horizontal outer side of the heat sink 1, which is arranged on a side of the heat sink 1 opposite the mounting side 9, is a cavity 11 via which the ends of the heat pipes 6 opposite the evaporation zone 10 are fluidically connected to one another, as a result of which a fluidic transition between the heat pipes 6 in the region of a condensation zone of the heat pipes 6 is also provided. In principle, this cavity 11, in particular a condensation zone connecting the heat pipes 6 to one another, is not absolutely necessary. This is associated with the fact that the heat pipes 6 are acted on over their entire length by the air stream passing through the heat sink 1 owing to their formation as a microchannel in the vertical fins 3 and therefore have a condensation zone distributed substantially over their entire vertical length.

FIG. 2 illustrates that the heat sink 1, in particular the air heat exchanger 2 thereof, is formed according to the principle of a microchannel heat exchanger in which the vertical fins 3 extending in the air flow direction through the heat exchanger over the entire depth of the heat sink 1 have a plurality of directly adjoining, but fluidically mutually separate microchannels 7 which each form a heat pipe, such that each fin 3 actually has a plurality of heat pipes.

The embodiment according to FIG. 3 shows an assembly comprising a further embodiment of a heat sink 1 which is mounted on an IT component 100 to be cooled, for example on a CPU chipset, via its mounting side 9. A radial fan 12 is configured to generate an air volume stream which passes through the heat sink 1 in the direction of the arrow. The radial fan 12 can be mounted on the air heat exchanger 2 via a mounting flange 13.

The features of the invention disclosed in the above description, in the drawing and in the claims can be essential for implementing the invention both individually and in any desired combination.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1-15. (canceled)

16. A heat sink for an electronic component, comprising a microchannel heat exchanger which is free of forward flow and return flow and has a hermetically encapsulated volume of a working medium and a plurality of fins which delimit air ducts through the microchannel heat exchanger, wherein the fins are at least partially in the form of a heat pipe wherein .the fins in the form of a heat pipe are formed as media-conducting hollow fins, each having at least one vertical hollow conductor or microchannel in which a working medium of the heat pipe is guided,
wherein the hollow fins are formed between an evaporation zone in a lower region of the microchannel heat exchanger and a cavity in the upper region of the microchannel heat exchanger and open into the latter, the hollow fins fluidically connecting a media volume of the evaporation zone to the cavity, so that all the heat pipes are fluidically connected to one another via the evaporation zone and the cavity,
wherein the microchannel heat exchanger has, in addition to the fins formed as heat pipes, further fins which extend substantially parallel to one another and spaced apart from one another and substantially perpendicular to the fins formed as heat pipes.

17. The heat sink as claimed in claim 16, in which the microchannels of the microchannel heat exchanger are each one of the heat pipes.

18. The heat sink as claimed in claim 17, in which the evaporation zone is in thermal contact with a mounting side of the heat sink for mounting the heat sink on an electronic component to be cooled.

19. The heat sink as claimed in claim 16, in which the microchannel heat exchanger has a cavity into which the microchannels open with their second ends arranged opposite the first.

20. The heat sink as claimed in claim 16, in which the further fins are in the form of solid fins made of a thermally conductive material, adjacent fins in the form of heat pipes being thermally coupled to one another via a plurality of the further fins.

21. The heat sink as claimed in claim 16, in which the fins in the form of heat pipes extend parallel to one another and are at a distance from one another which is less than 10 mm, preferably less than 8 mm and particularly preferably less than 6 mm.

22. The heat sink as claimed in claim 16, in which the fins in the form of heat pipes each have a plurality of vertical and parallel microchannels which are arranged one behind the other in a longitudinal direction of the fins in the form of heat pipes.

23. An assembly comprising at least one heat sink as claimed in claim 16 and an electronic component, wherein the heat sink is arranged in thermal contact on the electronic component, wherein the heat pipes have vertical hollow conductors or microchannels which extend vertically and perpendicularly to the electronic component at least in sections.

24. The assembly as claimed in claim 23, in which the heat sink is in thermal contact with the electronic component by way of a mounting side of the heat sink which is a heat coupling-in side of an evaporation zone of the heat pipes.

25. The assembly as claimed in claim 23, which has an air flow generator, preferably a fan, by means of which air is transported through the air-conducting channels, such that the air flows around the fins in the form of heat pipes.
